(19) United States
(12) Patent Application Publication
(10) Pub. No.: US 2023/0092242 A1
(43) Pub. Date: Mar. 23, 2023

(54) DIELECTRIC LAYER SEPARATING A METAL PAD OF A THROUGH GLASS VIA FROM A SURFACE OF THE GLASS

(71) Applicant: Intel Corporation, Santa Clara, CA (US)

(72) Inventors: Srinivas V. PIETAMBARAM, Chandler, AZ (US); Sameer PAITAL, Chandler, AZ (US); Kristof DARMAWIKARTA, Chandler, AZ (US); Hiroki TANAKA, Gilbert, AZ (US); Brandon C. MARIN, Gilbert, AZ (US); Jeremy D. ECTON, Gilbert, AZ (US); Gang DUAN, Chandler, AZ (US)

(21) Appl. No.: 17/507,010

(22) Filed: Sep. 17, 2021

(51) Int. Cl. H01L 23/15; H01L 21/768

(52) U.S. Cl. CPC H01L 23/15; H01L 21/76822; H01L 21/76867

(57) ABSTRACT

Embodiments described herein may be related to apparatuses, processes, and techniques directed to a glass core within a substrate in a package, with one or more through glass vias (TGV) that are filled with a conductive material to electrically couple a first side of the glass core with a second side of the glass layer opposite the first side. A pad, also of conductive material, is electrically and physically coupled with a first and/or second end of the conductive material of the TGV. A layer of dielectric material is between at least a portion of the pad and the surface of the glass core between the pad and the glass core during manufacturing, handling, and/or operation to facilitate a reduction of stress cracks in the glass core. Other embodiments may be described and/or claimed.

### FIELD

Embodiments of the present disclosure generally relate to the field of semiconductor packaging, and in particular to glass cores within package substrates.

### BACKGROUND

Continued growth in computing and mobile devices will continue to increase the demand for greater bandwidth density within and reliability of semiconductor packages.

### BRIEF DESCRIPTION OF THE DRAWINGS

FIG. 1 is a cross section side view of a legacy glass core substrate with a plurality of plated through glass vias (TGV) that have metal pads in contact with the glass core.

FIG. 2 shows a cross section side view and top-down views of a glass core substrate with a plurality of plated TGVs that have metal pads with a dielectric layer separating the metal pad from a surface of the glass core, in accordance with various embodiments.

FIGS. 3A-3B illustrates cross section side views of a package that includes a glass core substrate with a plurality of plated TGVs that have metal pads with the dielectric layer separating the metal pad from the surface of the glass core, one package including a passive element and another package including an active element, in accordance with various embodiments.

FIGS. 4A-4G illustrate stages in a manufacturing process for creating a package that includes a passive die and a glass core substrate that includes a plurality of plated TGV with a dielectric separating a metal pad coupled with the TGV from a surface of the glass core, in accordance with various embodiments.

FIGS. 5A-50 illustrate stages in a manufacturing process for creating a package that includes a active die and a glass core substrate that includes a plurality of plated TGV with a dielectric separating a metal pad coupled with the TGV from a surface of the glass core, in accordance with various embodiments.

FIG. 6 illustrates multiple examples of laser-assisted etching of glass interconnects processes, in accordance with various embodiments.

FIG. 7 illustrates an example of a process for creating a glass core that includes a plurality of plated TGV with a dielectric layer separating a metal pad coupled with the TGV from a surface of the glass core, in accordance with various embodiments.

FIG. 8 schematically illustrates a computing device, in accordance with various embodiments.

### DETAILED DESCRIPTION

Embodiments described herein may be related to apparatuses, processes, and techniques related to a glass layer, such as a glass core within a substrate in a package, that has one or more TGVs filled with a conductive material to form a pillar to electrically couple a first side of the glass layer with a second side of the glass layer opposite the first side. A pad, also of conductive material, is placed on a first and/or second end of the conductive material of the TGV to serve as electrical coupling. A layer of dielectric material, such as an ABF, is placed between the pad and a surface of the glass core, where the layer of dielectric material may absorb mechanical stress between the pad and the glass layer during manufacturing, handling, and/or operation. As a result, the layer of dielectric material facilitates the prevention of stress cracks in the glass layer proximate to the TGVs and the pads.

As silicon technology node continues to shrink, areas of focus for improving device performance include chip stacking using thinned chips, and increasing input/output (I/O) density within a substrate to facilitate multichip integration. These techniques benefit from a rigid carrier wafer, such as a glass layer, that may be based on a temporary bonding and debonding technology during package manufacturing. However, applying temporary bonding and debonding technology may result in warpage or shrinkage control issues after the removal of the rigid carrier. Frequently, after first level interconnect (FLI) bump formation, a substrate in the package will tend to warp due to residual stress of the manufacturing process and due to coefficient of thermal expansion (CTE) mismatches between various components within the package. For example, the CTEs of components within a package include silicon at 2.6 ppm/° C., ABF at ˜39 ppm/° C. and copper at 17 ppm/° C. Such warpage may, in turn, impact the backend process for mid-level interconnect (MLI) bump formation, and also the assembly thermal compression bonding (TCB) process.

In embodiments, a glass layer may be used as a permanent substrate core in packages. A glass layer, or glass core, is stiffer than an organic core. A glass core has a higher modulus of elasticity, for example ˜60-90 GPa, as compared to a modulus of elasticity of an organic core, for example ˜25-30 GPa. Thus, a glass layer, in addition to being very flat, also may restrict panel warpage and scaling, thereby maintaining, for example, a total thickness variation (TTV) amount of 2-3 μm for ≤30 μm bump pitch scaling. Warpage mitigation is particularly important for higher I/O density patterning.

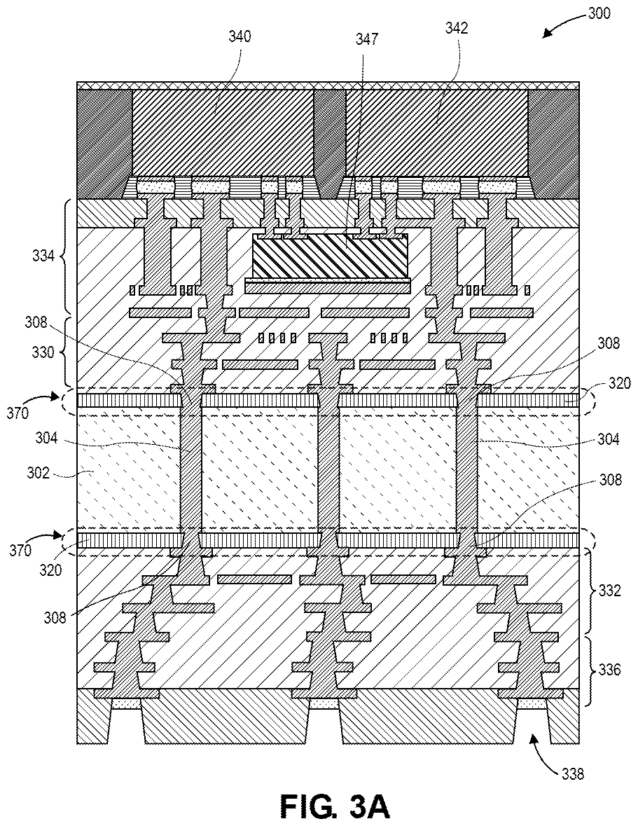

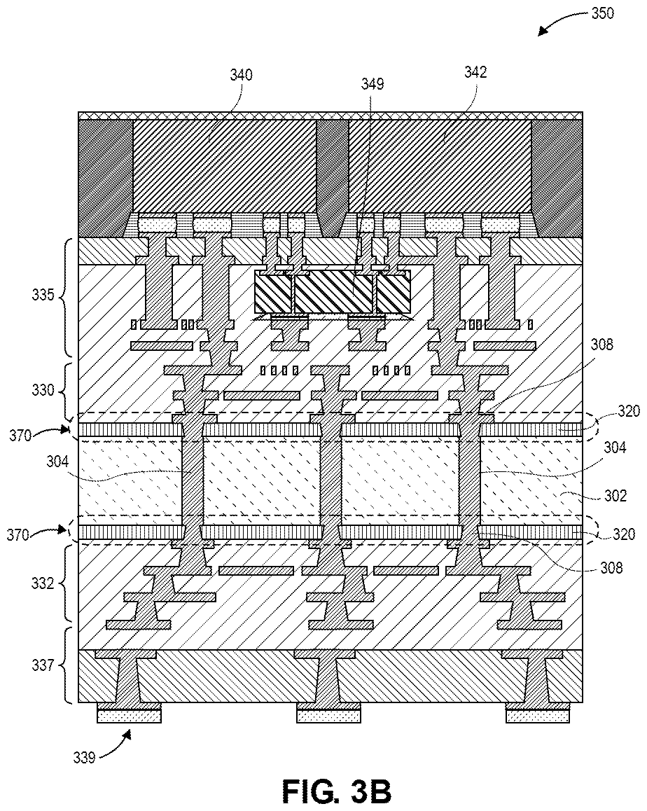

One of the draw backs associated with glass as a core is its fragility. Excess metallization around and within a glass core, in particular glass cores filled TGVs with pads on either side of the glass core, might result in excess stress during manufacturing and operation, and may result in micro cracks in the glass core. Embodiments described herein may include a dielectric layer, which may also be referred to as a dielectric reset layer, that may include ABF or any low-k dielectric. A top of the dielectric layer may be patterned over a TGV so that a subsequently deposited metal pad on the TGV will be separated from a surface of the glass layer by the dielectric layer. In embodiments, a high-speed I/O (HSIO) within the glass layer may be directly coupled to vias drilled within the dielectric layer, which may then be connected to patterned routing layers on top of the dielectric. Examples of this may be seen with respect to FIGS. 3A-3B.

As a result of these techniques, metallization on a surface of the glass core may be minimalized, and stress applied to the glass layer may be more effectively managed with improved package reliability.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

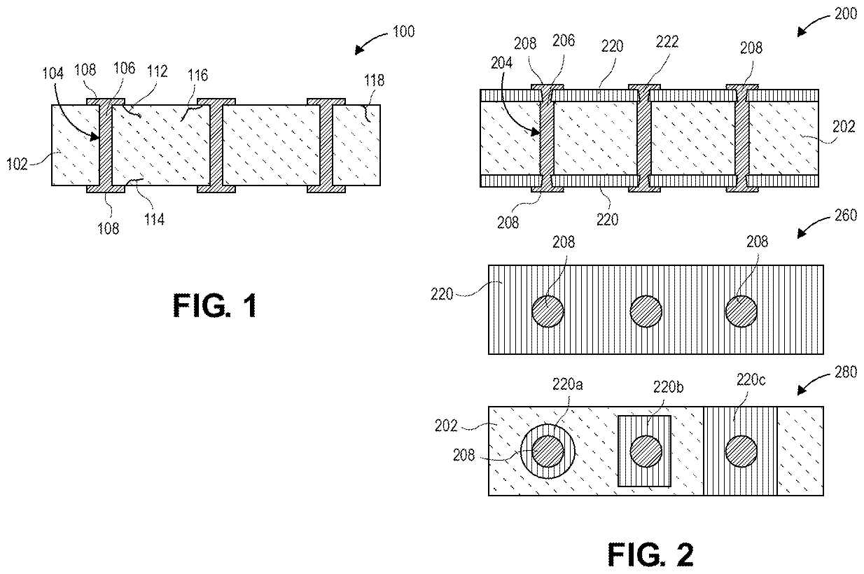

FIG. 1 is a cross section side view of a legacy glass core substrate with a plurality of plated TGVs that have metal pads in contact with the glass core. Legacy substrate 100 includes a glass core 102 with a plurality of TGV 104 extending from a top side of the glass core 102 to through a bottom side of the glass core 102. The TGV 104 may include a conductive material 106, such as copper, to electrically couple the top side and the bottom side of the glass core 102. The conductive material 106 may be completely filled within the TGV 104, or may be plated to a wall of the TGV 104.

Pads 108 may be physically and electrically coupled with the conductive material 106. As a result of the manufacturing process, the pads 108 are in physical contact with a surface of the glass core 102. Because the pads 108 and the conductive material 106 form a single metallic conductive unit, during operation they may provide stresses and strains to the surface or to the inner glass core 102, as shown by cracks 112, 114, 116, 118. These may result due to stress to the legacy substrate 100 during the manufacturing process, and due to a CTE mismatch between the conductive material 106 and the glass core 102. This CTE mismatch may be heightened during temperature variations that occur during manufacturing, or temperature variations that occur during operation of a package into which the substrate 100 may be located.

FIG. 2 shows a cross section side view and top-down views of a glass core substrate with a plurality of plated TGVs that have metal pads with a dielectric separating the metal pad from a surface of the glass core, in accordance with various embodiments. Substrate 200 includes a glass core 202 with a plurality of TGV 204 extending from a top side of the glass core 202 through a bottom side of the glass core 202. The TGV 204 may include a conductive material 206, such as copper, to electrically couple the top side and the bottom side of the glass core 202. The conductive material 206 may be completely filled within the TGV 204, or may be plated to a wall of the TGV 204.

In embodiments, a layer of dielectric material 220 may be placed on a surface of the glass core 202, with cavities 222 formed within the layer of dielectric material into which conductive material such as conductive material 206 may be placed. Pads 208 may be subsequently physically and electrically coupled with the conductive material 206.

As a result of the manufacturing process, the pads 208 are in physical contact with a surface of the layer of dielectric material 220. However, unlike FIG. 1, the pads 208 are not in direct physical contact with a surface of the glass core 202. Therefore, any stress that may result in a pressure from the pad 208 toward the glass core 202 will first be borne by the dielectric material 220 underneath the pad 208. Because the dielectric material 220 is more pliable than the glass core 202, the stress will not be transferred directly to the class core 202. In still other embodiments (not shown), the dielectric layer 220 may extend only under the pad 208, to ensure the metal pad is fully on the dielectric and isolated from the glass layer 202.

Diagram 260 shows a top-down view of substrate 200, with the dielectric layer 220 extending completely over a surface of the glass layer 202, with pads 208 exposed and available for electrical coupling during subsequent stages of manufacture that involve the substrate 200.

Diagram 280 shows a top-down view of another embodiment of substrate 200, where the dielectric layer 220 may be partially formed on a surface of the glass layer 202. In particular, the dielectric layer 220a may be a circular pattern that surrounds the pad 208. The dielectric layer 220b may be a rectangular, or other shape, that may extend partially on the surface of the glass core 202 but does not extend to the edge of the glass core 202. In embodiments, the dielectric layer 220c may extend from one edge of the glass core 202 to another. These are just example embodiments, other patterns may be implemented that are different from those shown.

FIG. 3A illustrates cross section side view of a package that includes a glass core substrate with a plurality of plated TGVs that have metal pads with the dielectric separating the metal pad from the surface of the glass substrate, one package including a passive element and another package including an active element, in accordance with various embodiments. Package 300 includes a glass core 302, a plurality of TGV 304 filled with a conductive material such as copper, a dielectric layer 320 physically coupled with sides of the glass core 302, and pads 308 that extend through and on to a surface of the dielectric layer 320, where the pads 308 are not physically coupled with a surface of the glass layer 302.

A first buildup layer 330 may be formed on a top side of the glass core 302, and a second buildup layer 332 may be formed on a bottom side of the glass core 302. Additional layers 334 may be formed on top of the first buildup layer 330, and include pillars and/or vias to electrically couple with a first die 340 and a second die 342. In embodiments, a passive element 347, for example a passive bridge, may be included within the additional layers 334 and which may be used to electrically couple the first die 340 with the second die 342. In embodiments, additional layers 336 may be coupled with the second buildup layer 332 to provide an electrical connection 338 to a bottom of the package 300.

FIG. 3B illustrates cross section side view of a package that includes a glass core substrate with a plurality of plated TGVs that have metal pads with the dielectric separating the metal pad from the surface of the glass substrate, one package including a passive element and another package including an active element, in accordance with various embodiments. Package 350, which may be similar to package 300, includes a glass core 302, a plurality of TGV 304 filled with a conductive material such as copper, a dielectric layer 320 physically coupled with sides of the glass core 302, and pads 308 that extend through and on a surface of the dielectric layer 320, where the pads 308 are not physically coupled with a surface of the glass core 302.

A first buildup layer 330 may be formed on a top side of the glass core 302, and a second buildup layer 332 may be formed on a bottom side of the glass core 302. Additional layers 335 may be formed on top of the first buildup layer 330, and include pillars and/or vias to electrically couple with a first die 340 and a second die 342. In embodiments, an active element 349, for example an active bridge or other component that includes through silicon vias (TSV), may be included within the additional layers 335 and which may be used to electrically couple the first die 340, the second die 342, and also to other electrical features within the package 350. In embodiments, additional layers 337 may be coupled with the second buildup layer 332 to provide an electrical connection 339 to a bottom of the package 350.

As shown in area 370 with respect to both packages 300, 350, stress is reduced on the glass core 302 by having pads 308 extend through and over the top of the dielectric layer 320, rather than the pads 308 extending directly over the top of the glass core 302.

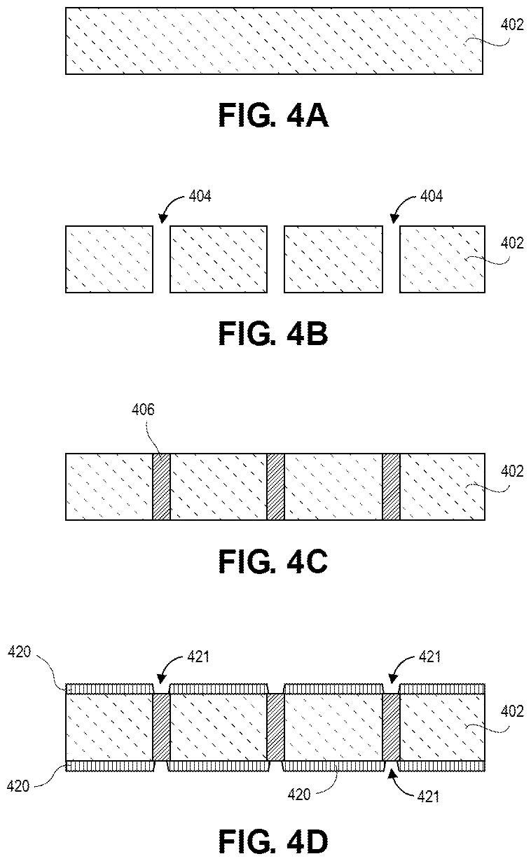

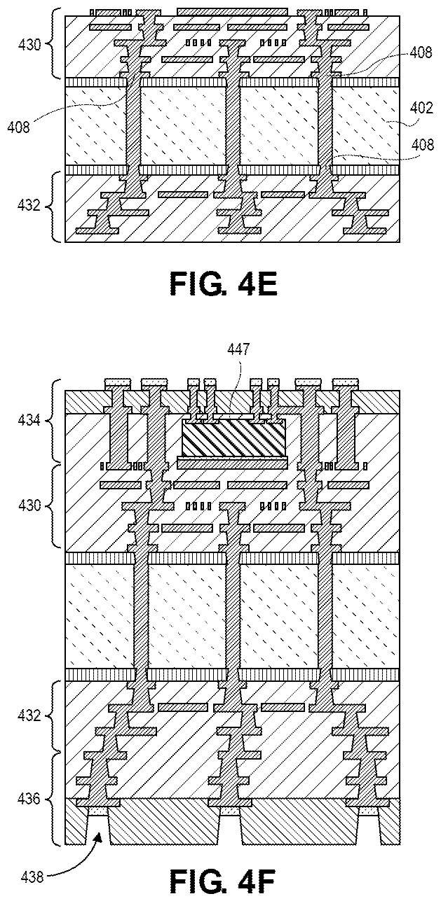

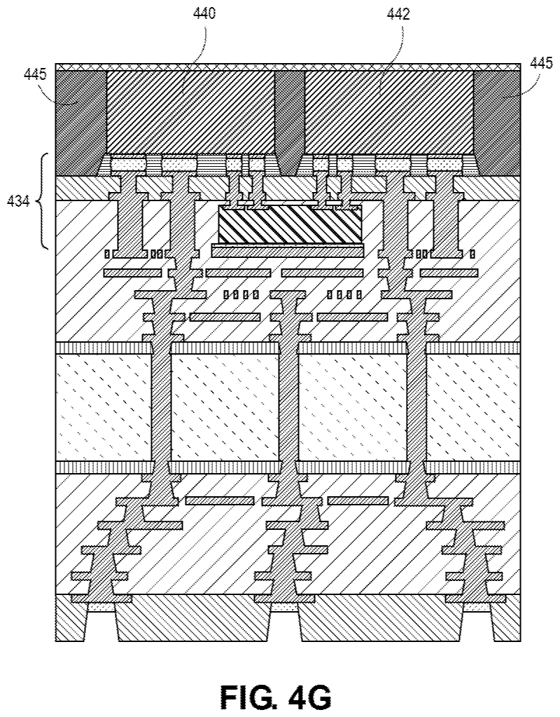

FIGS. 4A-4G illustrate stages in a manufacturing process for creating a package that includes a passive die and a glass core substrate that includes a plurality of plated TGV with a dielectric layer separating a metal pad coupled with the TGV from a surface of the glass core, in accordance with various embodiments. FIG. 4A illustrates a stage in the manufacturing process where a glass layer 402 is identified. In embodiments, the glass layer 402 may also be referred to as the glass core of the package, and may have a thickness based on rigidity characteristics for the package to facilitate increased reliability during manufacture, installation, and operation of the package.

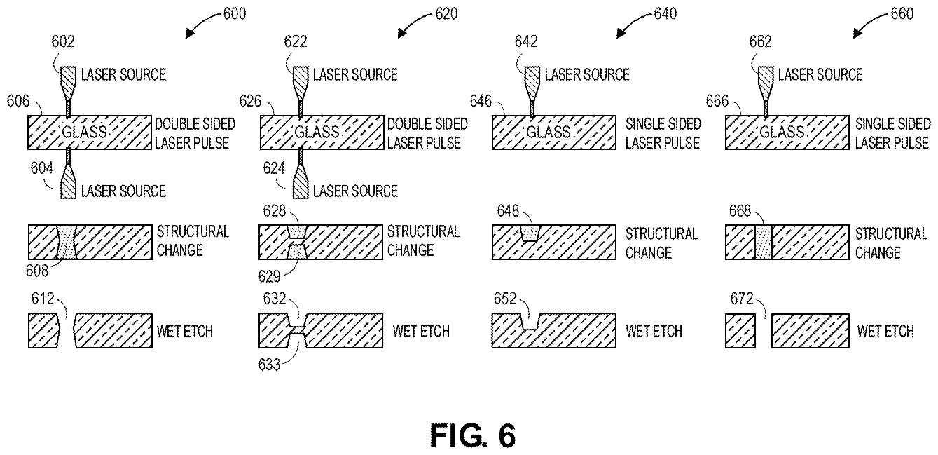

FIG. 4B illustrates a stage in the manufacturing process where TGVs 404 are formed within the glass layer 402. In embodiments, the TGVs 404 may be formed using a drilling technique, for example a laser sensing etch technique, or using the techniques described with respect to FIG. 6 below.

FIG. 4C illustrates a stage in the manufacturing process where the TGVs 404 are plated with a conductive material, such as copper, producing copper pillars 406. In embodiments, the copper pillars 406 may be filled with a conductive material, or the conductive material may be plated on the wall of the TGVs 404. In embodiments, after plating, the resulting glass core 402 may be planarized to grind out excess conductive material (not shown) that may be on the top of the glass core 402.

FIG. 4D illustrates a stage in the manufacturing process where a dielectric layer 420 is laminated on the sides of the glass core 402. This dielectric layer 420 may also be referred to as a dielectric reset layer. Subsequent to the lamination of the dielectric layer 420, vias 421 may be drilled into the dielectric layer 420 using a laser via drill process, or using some other drilling technique.

FIG. 4E illustrates a stage in the manufacturing process where the vias 421 are plated to form pads 408. Subsequently, a first redistribution layer (RDL) 430 may be formed on the top side of the glass core 402 and a second RDL 432 may be formed on the bottom side of the glass core 402.

FIG. 4F illustrates a stage in the manufacturing process where additional layers 434 are added to the top of the first RDL 430. In addition, in embodiments, layers 436 may be added to the bottom of the second RDL 432. The additional layers 434 include a passive element 447, for example a passive bridge, which may be used to electrically couple the first die 440 with the second die 442 as described in further detail with respect to FIG. 4G below. The additional layers 436 may provide electrical couplings 438 for the bottom side of the package.

FIG. 4G illustrates a stage in the manufacturing process where dies 440, 442 are coupled with the additional layers 434. In embodiments, a molding 445 may be placed to surround and secure the dies 440, 442 within the package.

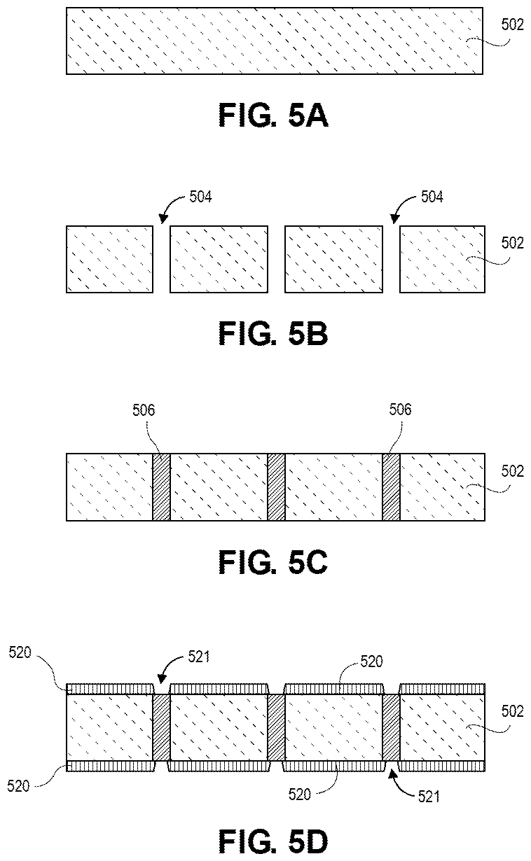

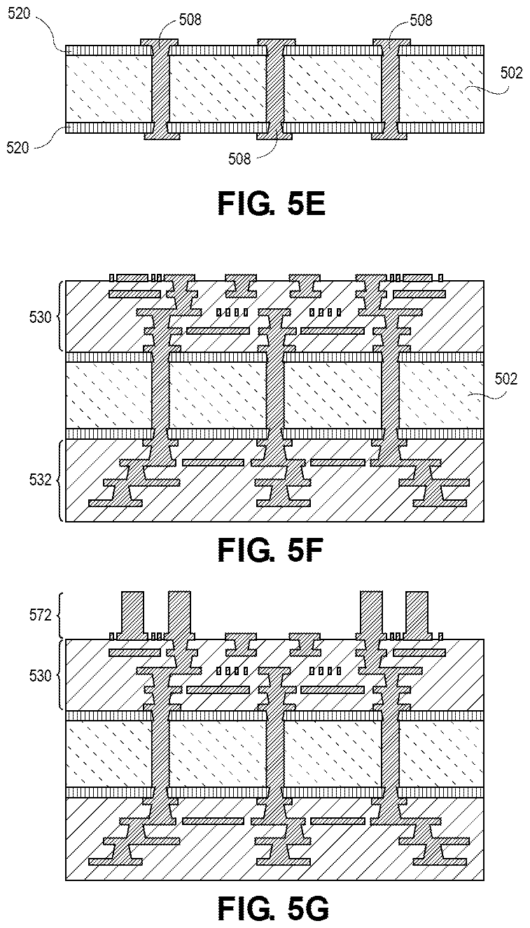

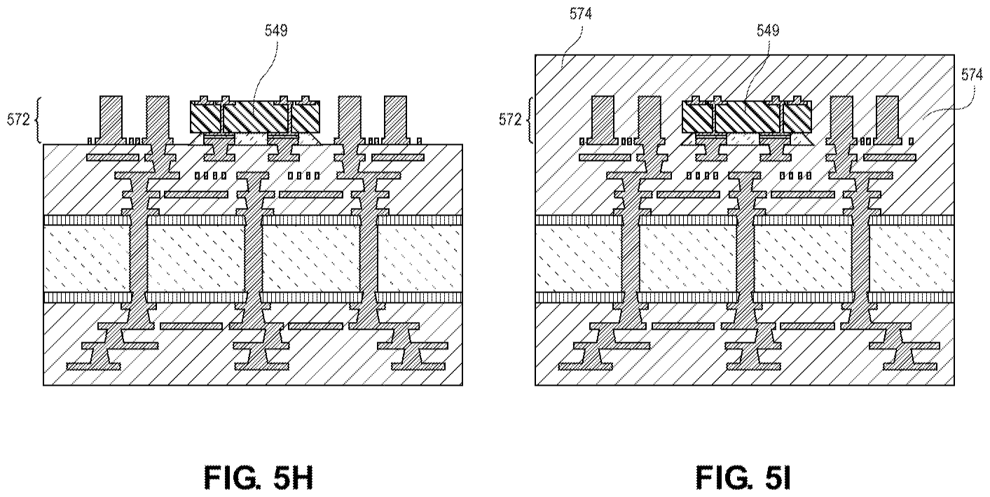

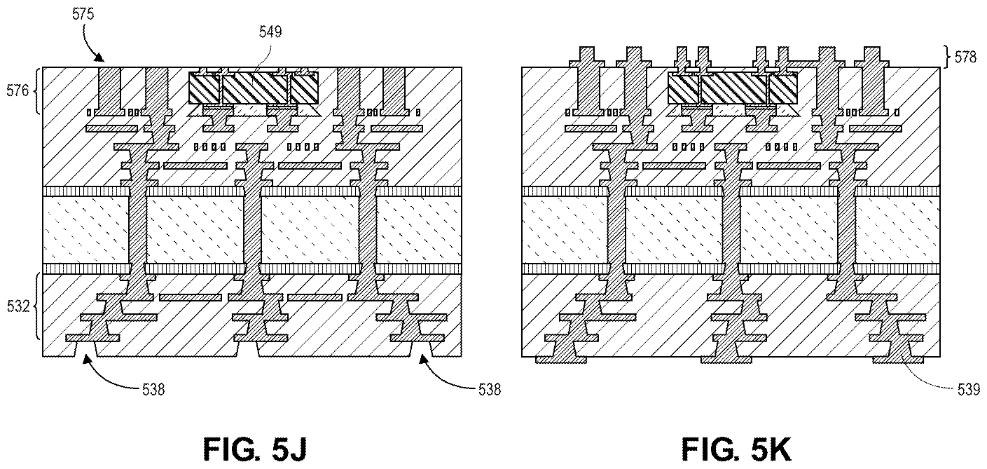

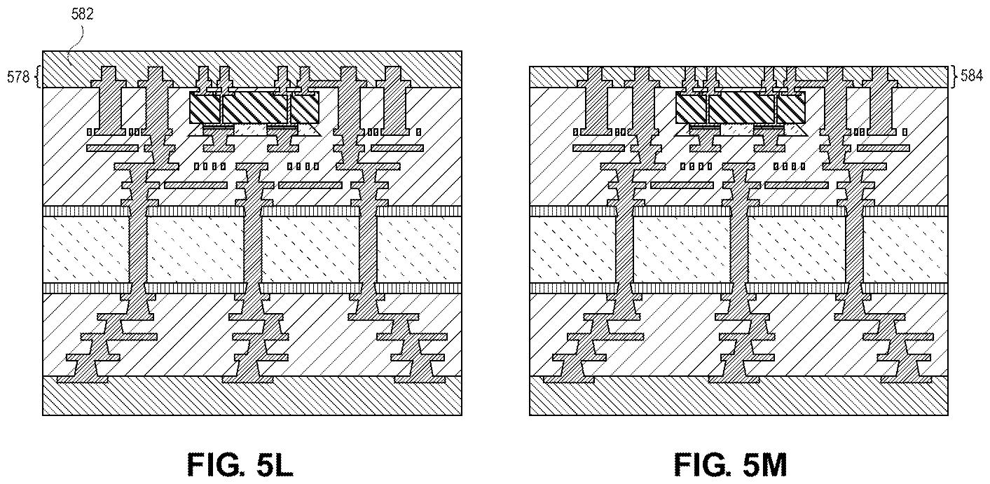

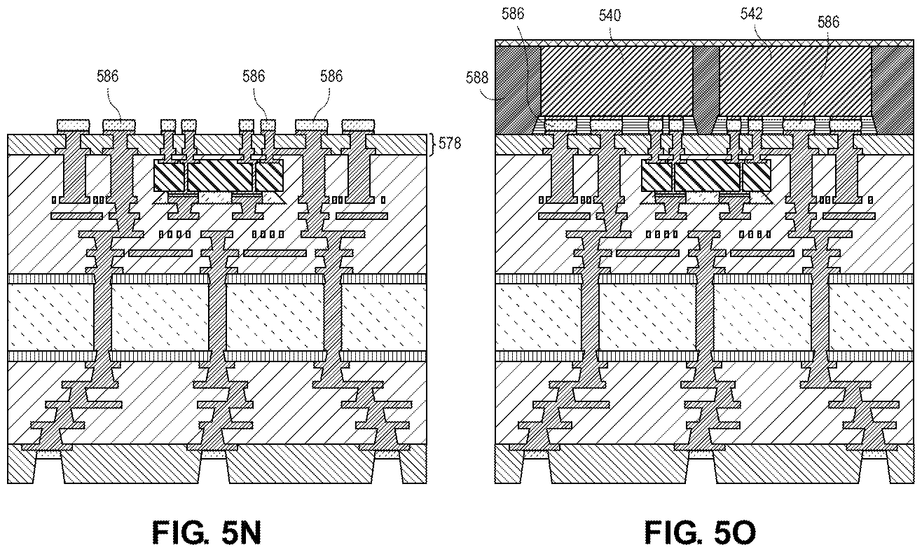

FIGS. 5A-50 illustrate stages in a manufacturing process for creating a package that includes an active die and a glass core substrate that includes a plurality of plated TGV with a dielectric separating a metal pad coupled with the TGV from a surface of the glass core, in accordance with various embodiments. FIG. 5A illustrates a stage in the manufacturing process where a glass layer 502 is identified. In embodiments, the glass layer 502 may also be referred to as the glass core of the package, and may have a thickness based on rigidity characteristics for the package to facilitate increased reliability during manufacture, installation, and operation of the package.

FIG. 5B illustrates a stage in the manufacturing process where TGVs 504 are formed within the glass layer 502. In embodiments, the TGVs 504 may be formed using a drilling technique, for example a laser sensing etch technique, or using the techniques described with respect to FIG. 6 below.

FIG. 5C illustrates a stage in the manufacturing process where the TGVs 504 are plated with a conductive material, such as copper, producing copper pillars 506. In embodiments, the copper pillars 506 may be filled using a plating technique with a conductive material, or the conductive material may be plated on the wall of the TGVs 504. In embodiments, after plating, the resulting glass core 502 may be planarized to grind out excess conductive material (not shown) that may be on the top of the glass core 502.

FIG. 5D illustrates a stage in the manufacturing process where a dielectric layer 520 is laminated on the sides of the glass core 502. This dielectric layer 520 may also be referred to as a dielectric reset layer. Subsequent to the lamination of the dielectric layer 520, vias 521 may be drilled into the dielectric layer 520 using a laser via drill process, or using some other drilling technique.

FIG. 5E illustrates a stage in the manufacturing process where pads 508 are formed within the vias 521. Note that a portion of the pads 508 overlap the dielectric layer 520, while these overlapping portions do not come into direct physical contact with a side of the glass core 502.

FIG. 5F illustrates a stage the manufacturing process where a first RDL layer 530 is formed and is electrically and physically coupled with the top side of the glass core 502, and a second RDL layer 532 is formed and is electrically and physically coupled with the bottom side of the glass core 502.

FIG. 5G illustrates a stage in the manufacturing process where copper pillars 572 are formed on a top side of the first RDL 530.

FIG. 5H illustrates a stage in the manufacturing process where an active element 549 is applied at the top of the first RDL layer 530. In embodiments, the active element 549 may be an active silicon bridge, or some other functional die that may include TSVs through the active element 549 to electrically couple the first RDL 530 with electrical circuitry within the active element 549. In embodiments, the active element 549 may be attached using solder bonding or a die mount.

FIG. 5I illustrates a stage in the manufacturing process where the copper pillars 572 and the active element 549 are encapsulated within a dielectric material 574.

FIG. 5J illustrates a stage in the manufacturing process where a portion of the dielectric material 574 has been ground away 575 to reveal the layers 576 that include copper pillars and active element 549 routing layers. In addition, vias 538 may be formed on the backside to expose electrical pads located within the second RDL 532. In embodiments, the vias 538 may be formed using a via drill process.

FIG. 5K illustrates a stage in the manufacturing process where a top layer 578 is formed that may include one or more routing layers, copper pads, and/or copper pillars. In addition, copper pads 539 may be plated in the vias 538 on the backside of the package.

FIG. 5L illustrates a stage in the manufacturing process where a solder resist layer 582 is placed over the top layer 578.

FIG. 5M illustrates a stage in the manufacturing process where the solder resist layer 582 has been polished or ground to form top layer 584, where the electrical connections of top layer 578 of FIG. 5L may be exposed.

FIG. 5N illustrates a stage in the manufacturing process where first level interconnects (FLI) 586 are formed on the electrical connections of top layer 578.

FIG. 5O illustrates a stage in the manufacturing process where dies 540, 542 are electrically and physically coupled to the FLIs 586. In embodiments, a mold 588 may be formed around the dies 540, 542 to provide additional mechanical stability.

FIG. 6 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass core substrate. In embodiments, different process parameters may be adjusted to achieve drills of various shapes and depths, thus opening the door for innovative devices, architectures, processes, and designs in glass core. Embodiments, such as the bridge discussed herein, may also take advantage of these techniques.

Diagram 600 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 612 is created by laser pulses from two laser sources 602, 604 on opposite sides of a glass wafer 606. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 602, 604 are applied perpendicularly to the glass wafer 606 to induce a morphological change 608, which may also be referred to as a structural change, in the glass that encounters the laser pulses. This morphological change 608 includes changes in the molecular structure of the glass to make it easier to etch out (remove a portion of the glass). In embodiments, a wet etch process may be used.

Diagram 620 shows a high level process flow for a double blind shape. A double blind shape 632, 633 may be created by laser pulses from two laser sources 622, 624, which may be similar to laser sources 602, 604, that are on opposite sides of the glass wafer 626, which may be similar to glass wafer 606. In this example, adjustments may be made in the laser pulse energy and/or the laser pulse exposure time from the two laser sources 622, 624. As a result, morphological changes 628, 629 in the glass 626 may result, with these changes making it easier to etch out portions of the glass. In embodiments, a wet etch process may be used.

Diagram 640 shows a high level process flow for a single-blind shape, which may also be referred to as a trench. In this example, a single laser source 642 delivers a laser pulse to the glass wafer 646 to create a morphological change 648 in the glass 646. As described above, these morphological changes make it easier to etch out a portion of the glass 652. In embodiments, a wet etch process may be used.

Diagram 660 shows a high level process flow for a through via shape. In this example, a single laser source 662 applies a laser pulse to the glass 666 to create a morphological change 668 in the glass 666, with the change making it easier to etch out a portion of the glass 672. As shown here, the laser pulse energy and/or laser pulse exposure time from the laser source 662 has been adjusted to create an etched out portion 672 that extends entirely through the glass 666.

With respect to FIG. 6, although embodiments show laser sources 602, 604, 622, 624, 642, 662 as perpendicular to a surface of the glass 606, 626, 646, 666, in embodiments, the laser sources may be positioned at an angle to the surface of the glass, with pulse energy and/or pulse exposure time variations in order to cause a diagonal via or a trench, or to shape the via, such as 612, 672, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 6, through hole vias 612, 672 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias may result in better signaling, allowing more I/O signals to be routed through the glass wafer and to other coupled components such as a substrate.

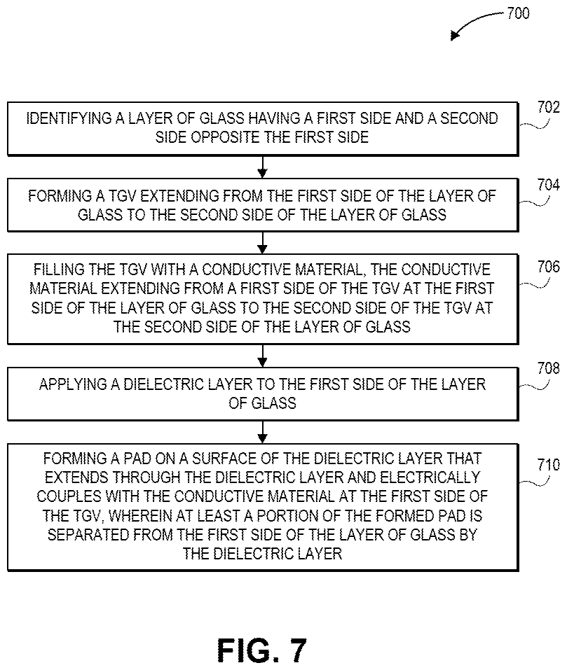

FIG. 7 illustrates an example of a process for creating a glass core that includes a plurality of plated TGV with a dielectric layer separating a metal pad coupled with the TGV from a surface of the glass core substrate, in accordance with various embodiments. Process 700 may be implemented using the systems, processes, techniques, and/or apparatus described herein, and in particular with respect to FIGS. 1-6.

At block 702, the process may include identifying a layer of glass having a first side and a second side opposite the first side.

At block 704, the process may further include forming a TGV extending from the first side of the layer of glass to the second side of the layer of glass.

At block 706, the process may further include filling the TGV with a conductive material, the conductive material extending from a first side of the TGV at the first side of the layer of glass to the second side of the TGV at the second side of the layer of glass.

At block 708, the process may further include applying a dielectric layer to the first side of the layer of glass.

At block 710, the process may further include forming a pad on a surface of the dielectric layer that extends through the dielectric layer and electrically couples with the conductive material at the first side of the TGV, wherein at least a portion of the formed pad is separated from the first side of the layer of glass by the dielectric layer.

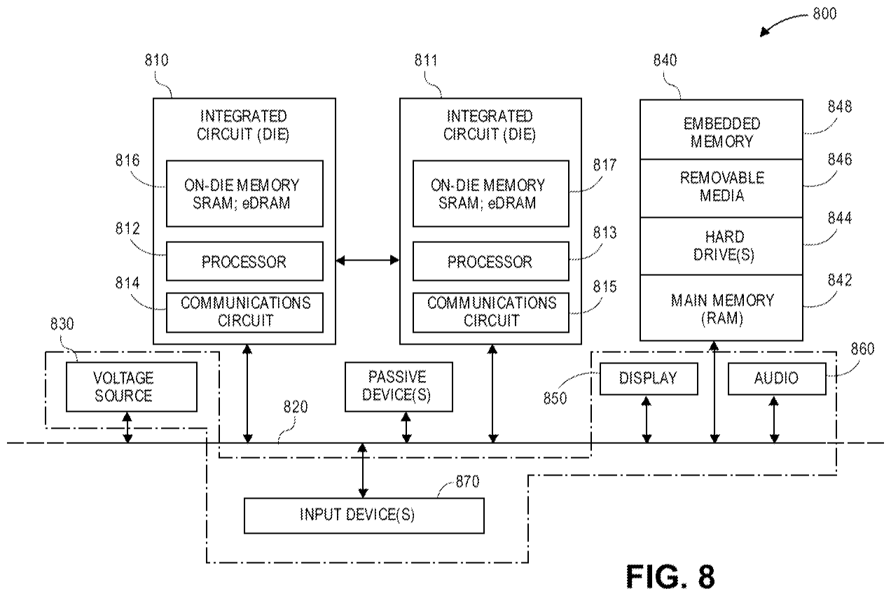

FIG. 8 is a schematic of a computer system 800, in accordance with an embodiment of the present invention. The computer system 800 (also referred to as the electronic system 800) as depicted can embody a dielectric layer separating a metal pad of a through glass via from the surface of the glass, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, a dielectric layer separating a metal pad of a through glass via from the surface of the glass, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having a dielectric layer separating a metal pad of a through glass via from the surface of the glass, according to any of the several disclosed embodiments and their equivalents, an electronic system, a computer system, one or more methods of fabricating an integrated circuit, and one or more methods of fabricating an electronic assembly that includes a package substrate having a dielectric layer separating a metal pad of a through glass via from the surface of the glass, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a dielectric layer separating a metal pad of a through glass via from the surface of the glass embodiments and their equivalents. A foundation substrate may be included, as represented by the dashed line of FIG. 8. Passive devices may also be included, as is also depicted in FIG. 8.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a substrate comprising: a layer of glass having a first side and a second side opposite the first side; a through glass via (TGV) extending from the first side of the layer of glass to the second side of the layer of glass; a conductive metal within the TGV that electrically couples the first side of the layer of glass with the second side of the layer of glass; a pad coupled with the conductive metal at the first side of the layer of glass, wherein a layer of dielectric material is between at least a portion of the pad and the first side of the layer of glass.

Example 2 includes a substrate of example 1, wherein the pad includes the conductive metal.

Example 3 includes the substrate of example 1, wherein the conductive metal completely fills the TGV.

Example 4 includes the substrate of example 1, wherein the layer of dielectric material is completely between the pad and the first side of the layer of glass, wherein the pad is not directly coupled with the first side of the layer of glass.

Example 5 includes the substrate of example 1, wherein the pad is a first pad, and wherein the layer of dielectric material is a first layer of dielectric material; and further comprising: a second pad coupled with the conductive metal at the second side of the layer of glass, wherein a second layer of dielectric material is between at least a portion of the second pad and the second side of the glass layer.

Example 6 includes the substrate of example 5, wherein the second pad is not directly coupled with the second side of the layer of glass.

Example 7 includes the substrate of example 5, wherein the second layer of dielectric material is completely between the second pad and the second side of the layer of glass, wherein the second pad is not directly coupled with the second side of the layer of glass.

Example 8 includes the substrate of example 5, wherein the first layer of dielectric material completely covers a surface of the first side of the layer of glass, and wherein the second layer of dielectric material completely covers a surface of the second side of the layer of glass.

Example 9 includes the substrate of example 5, wherein the TGV is a plurality of TGVs.

Example 10 includes the substrate of any one of examples 1-9, wherein the dielectric material has a thickness between 2-100 μm.

Example 11 includes the substrate of any one of examples 1-9, where in the pad has a width of at least 5 μm.

Example 12 is a method comprising: identifying a layer of glass having a first side and a second side opposite the first side; forming a through glass via (TGV) extending from the first side of the layer of glass to the second side of the layer of glass; filling the TGV with a conductive material, the conductive material extending from a first side of the TGV at the first side of the layer of glass to the second side of the TGV at the second side of the layer of glass; applying a dielectric layer to the first side of the layer of glass; and forming a pad on a surface of the dielectric layer that extends through the dielectric layer and electrically couples with the conductive material at the first side of the TGV, wherein at least a portion of the formed pad is separated from the first side of the layer of glass by the dielectric layer.

Example 13 includes the method of example 12, wherein the pad is a first pad and the dielectric layer is a first dielectric layer; and further comprising: applying a second dielectric layer to the second side of the layer of glass; and forming a second pad on a surface of the second dielectric layer that extends through the second dielectric layer and electrically couples with the conductive material at the second side of the TGV, wherein at least a portion of the formed second pad is separated from the second side of the layer of glass by the second dielectric layer.

Example 14 includes the method of example 13, wherein the TGV is a plurality of TGVs.

Example 15 includes the method of example 13, wherein the first pad is electrically coupled with the second pad.

Example 16 includes the method of example 13, wherein the conductive material is copper or a copper alloy.

Example 17 includes the method of example 13, wherein the first layer of dielectric material is completely between the first pad and the first side of the layer of glass, wherein the first pad is not directly coupled with the first side of the layer of glass; and wherein the second layer of dielectric material is completely between the second pad and the second side of the layer of glass, wherein the second pad is not directly coupled with the second side of the layer of glass.

Example 18 includes the method of any one of examples 13-17, wherein a thickness of the dielectric material is between 2-100 μm.

Example 19 is a package comprising: a substrate comprising: a layer of glass having a first side and a second side opposite the first side; a through glass via (TGV) extending from the first side of the layer of glass to the second side of the layer of glass; a conductive metal within the TGV that electrically couples the first side of the layer of glass with the second side of the layer of glass; a first pad coupled with the conductive metal at the first side of the layer of glass, wherein a first layer of dielectric material is between at least a portion of the first pad and the first side of the layer of glass; and a second pad coupled with the conductive metal at the second side of the layer of glass, wherein a second layer of dielectric material is between at least a portion of the second pad and the second side of the layer of glass; and a buildup layer coupled with the first pad and the first layer of dielectric material, wherein at least one routing layer within the buildup layer is electrically coupled with the first pad.

Example 20 includes the package of example 19, wherein the buildup layer is the first buildup layer, and further comprising: a second buildup layer coupled with the second pad and the second layer of dielectric material.

Example 21 includes the package of example 19, wherein the first pad in the second pad include the conductive metal.

Example 22 includes the package of example 19, wherein the dielectric material is in ABF.

Example 23 includes the package of example 19, wherein the conductive metal is copper or a copper alloy.

Example 24 includes the package of example 19, wherein the buildup layer includes an encapsulated bridge or an encapsulated die.

Example 25 includes the package of example 19, wherein a thickness of the dielectric material is between 2-100 μm.

What is claimed is:

1. A substrate comprising:
a layer of glass having a first side and a second side opposite the first side;
a through glass via (TGV) extending from the first side of the layer of glass to the second side of the layer of glass;
a conductive metal within the TGV that electrically couples the first side of the layer of glass with the second side of the layer of glass;
a pad coupled with the conductive metal at the first side of the layer of glass, wherein a layer of dielectric material is between at least a portion of the pad and the first side of the layer of glass.

2. The substrate of claim 1, wherein the pad includes the conductive metal.

3. The substrate of claim 1, wherein the conductive metal completely fills the TGV.

4. The substrate of claim 1, wherein the layer of dielectric material is completely between the pad and the first side of the layer of glass, wherein the pad is not directly coupled with the first side of the layer of glass.

5. The substrate of claim 1, wherein the pad is a first pad, and wherein the layer of dielectric material is a first layer of dielectric material; and further comprising:
a second pad coupled with the conductive metal at the second side of the layer of glass, wherein a second layer of dielectric material is between at least a portion of the second pad and the second side of the glass layer.

6. The substrate of claim 5, wherein the second pad is not directly coupled with the second side of the layer of glass.

7. The substrate of claim 5, wherein the second layer of dielectric material is completely between the second pad and the second side of the layer of glass, wherein the second pad is not directly coupled with the second side of the layer of glass.

8. The substrate of claim 5, wherein the first layer of dielectric material completely covers a surface of the first side of the layer of glass, and wherein the second layer of dielectric material completely covers a surface of the second side of the layer of glass.

9. The substrate of claim 5, wherein the TGV is a plurality of TGVs.

10. The substrate of claim 1, wherein the dielectric material has a thickness between 2-100 μm.

11. The substrate of claim 1, where in the pad has a width of at least 5 μm.

12. A method comprising:
identifying a layer of glass having a first side and a second side opposite the first side;
forming a through glass via (TGV) extending from the first side of the layer of glass to the second side of the layer of glass;
filling the TGV with a conductive material, the conductive material extending from a first side of the TGV at the first side of the layer of glass to the second side of the TGV at the second side of the layer of glass;
applying a dielectric layer to the first side of the layer of glass; and
forming a pad on a surface of the dielectric layer that extends through the dielectric layer and electrically couples with the conductive material at the first side of the TGV, wherein at least a portion of the formed pad is separated from the first side of the layer of glass by the dielectric layer.

13. The method of claim 12, wherein the pad is a first pad and the dielectric layer is a first dielectric layer; and further comprising:
applying a second dielectric layer to the second side of the layer of glass; and
forming a second pad on a surface of the second dielectric layer that extends through the second dielectric layer and electrically couples with the conductive material at the second side of the TGV, wherein at least a portion of the formed second pad is separated from the second side of the layer of glass by the second dielectric layer.

14. The method of claim 13, wherein the TGV is a plurality of TGVs.

15. The method of claim 13, wherein the first pad is electrically coupled with the second pad.

16. The method of claim 13, wherein the conductive material is copper or a copper alloy.

17. The method of claim 13, wherein the first layer of dielectric material is completely between the first pad and the first side of the layer of glass, wherein the first pad is not directly coupled with the first side of the layer of glass; and wherein the second layer of dielectric material is completely between the second pad and the second side of the layer of glass, wherein the second pad is not directly coupled with the second side of the layer of glass.

18. The method of claim 13, wherein a thickness of the dielectric material is between 2-100 μm.

19. A package comprising:
a substrate comprising:
a layer of glass having a first side and a second side opposite the first side;
a through glass via (TGV) extending from the first side of the layer of glass to the second side of the layer of glass;
a conductive metal within the TGV that electrically couples the first side of the layer of glass with the second side of the layer of glass;
a first pad coupled with the conductive metal at the first side of the layer of glass, wherein a first layer of dielectric material is between at least a portion of the first pad and the first side of the layer of glass; and
a second pad coupled with the conductive metal at the second side of the layer of glass, wherein a second layer of dielectric material is between at least a portion of the second pad and the second side of the layer of glass; and
a buildup layer coupled with the first pad and the first layer of dielectric material, wherein at least one routing layer within the buildup layer is electrically coupled with the first pad.

20. The package of claim 19, wherein the buildup layer is the first buildup layer, and further comprising:
a second buildup layer coupled with the second pad and the second layer of dielectric material.

21. The package of claim 19, wherein the first pad in the second pad include the conductive metal.

22. The package of claim 19, wherein the dielectric material is in ABF.

23. The package of claim 19, wherein the conductive metal is copper or a copper alloy.

24. The package of claim 19, wherein the buildup layer includes an encapsulated bridge or an encapsulated die.

25. The package of claim 19, wherein a thickness of the dielectric material is between 2-100 μm.
